(19) United States
(12) Patent Application Publication
(10) Pub. No.: US 2017/0288082 A1
(43) Pub. Date: Oct. 5, 2017

(54) SEMICONDUCTOR STRUCTURE, METHOD FOR THE PRODUCTION THEREOF AND USE THEREOF

(71) Applicant: FRAUNHOFER-GESELLSCHAFT ZUR FÖRDERUNG DER ANGEWANDTEN FORSCHUNG E.V., München (DE)

(72) Inventors: Stefan REBER, Gundelfingen (DE); Stefan LINDEKUGEL, Denzlingen (DE); Regina PAVLOVIC, Freiburg (DE)

(73) Assignee: FRAUNHOFER-GESELLSCHAFT ZUR FÖRDERUNG DER ANGEWANDTEN FORSCHUNG E.V., München (DE)

(21) Appl. No.: 15/507,171

(22) PCT Filed: Aug. 26, 2015
(86) PCT No.: PCT/EP2015/069496

§ 371 Date: Feb. 27, 2017

(30) Foreign Application Priority Data
Aug. 28, 2014 (DE) 10 2014 217 165.2

(51) Int. Cl. H01L 31/054; H01L 31/046; H01L 31/18

(52) U.S. Cl. CPC H01L 31/0547; H01L 31/1896; H01L 31/046

(57) ABSTRACT

The invention relates to a semiconductor structure made of a substrate and a semiconductor layer which are bonded integrally to each other via a thermally and/or chemically cured adhesive. Likewise, the invention relates to a method for the production of such integral bonds. Use in such semiconductor structures, in particular as solar cell or solar cell module.

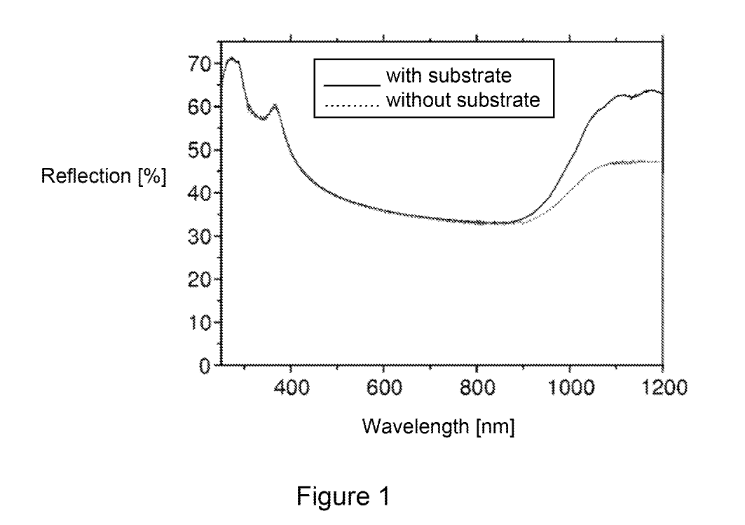

The invention relates to a semiconductor structure made of a substrate and a semiconductor layer which are bonded integrally to each other via a thermally and/or chemically cured adhesive. Likewise, the invention relates to a method for the production of such integral bonds. Use in such semiconductor structures, in particular as solar cell or solar cell module.

One approach for reducing the production costs of photovoltaic modules is the use of a thin silicon layer which, for mechanical stabilisation, is processed on an inexpensive substrate. The thin layers can be produced in various ways, one possibility being the silicon-layer transfer process. Here, a thin silicon layer is used as nucleation layer for the epitaxial growth of the active layer and is detached from a wafer or also directly from a block. Since free-standing layers can run through the further processes to form the solar cell only with a low yield, it is obvious to reinforce them by means of a stable substrate.

Solar cells which are produced by means of the layer-transfer process are often only detached from the mother substrate at a later point in time in the solar cell process and secured on a glass substrate with silicone.

Other possibilities are the production of a bond at an atomic level between the detached layer and the substrate (“bonding”, e.g. on silicon or glass), in which case both surfaces must be very smooth and clean or by means of aluminium alloying, a conductive bond being produced.

Both the substrate and the bond between substrate and silicon foil must withstand the following process steps. The requirements for the bonding layer vary according to the concept.

Thus, e.g. the detachment can be effected before or after the epitaxial thickening, which involves different requirements for temperature resistance and/or for the purity of the material. Formation of an atomic bond is associated with extremely high requirements for purity and surface polishing, therefore this process will scarcely fulfil the necessary cost requirements of a non-concentrating PV technology.

For use in particular in the field of production of photovoltaic modules, the adhesive must fulfil the following requirements:
1. No damage to the generally thin layers is effected by the bonding process
2. The adhesive must be stable relative to high temperatures
3. The mechanical stability of the adhesive must satisfy the process conditions of the module production
4. Degassing of impurities in the adhesive at high temperatures should be avoided
5. Conductive and also electrically insulating adhesive layers should likewise be made possible.

Various solution approaches have been known to date from the state of the art, none can however entirely fulfil the mentioned requirements.

Thus an alloy with low-melting metals is known from V. Gazuz, et al., Novel n-type silicon solar cell device by aluminium bonding to a glass substrate, in Proc. 24, European Photovoltaic Solar Energy Conference and Exhibition, Hamburg, Germany, 2009, p. 2206-2208. In this method, the result can however be a loss of the bonding effect at process temperatures of approx. 1,000° C. Problems with respect to soiling or damaging of the silicon layers or also degassing of impurities likewise occur.

A comparable method is described in L. Wang, et al., 16.8% Efficient Ultra-Thin Silicon Solar Cells on Steel, in Proc. 28th European Photovoltaic Solar Energy Conference and Exhibition, Paris, France, 2013, p. 2641-2644, which likewise has the previously mentioned disadvantages.

A further option resides in the use of silicone as adhesive directly on the module glass. Because of the low thermal stability of silicones, these systems are however no longer usable in high-temperature treatment steps above 200° C. This technology is described in F. Dross, et al., Crystalline thin-foil silicon solar cells: where crystalline quality meets thin-film processing, Prog. Photovolt: Res. Appl. 2012, 20, p. 770-784.

Starting herefrom, it was the object of the present invention to provide a semiconductor structure which is produced by an integral bond of a substrate to a semiconductor layer, the adhesive layer used for the integral bond having high temperature stability. Likewise, it would be desirable if the adhesive layers were provided in an electrically conductive or electrically insulating form.

This object is achieved by the semiconductor structure having the features of claim 1 and by the method for the production having the features of claim 12. In claim 16, uses according to the invention are indicated. The further dependent claims reveal advantageous developments.

According to the invention, a semiconductor structure made of at least one substrate and at least one semiconductor layer applied on the substrate, at least in regions, is provided, a first semiconductor layer being bonded integrally to the substrate, at least in regions, by means of a thermally and/or chemically cured adhesive. The cured adhesive thereby has a thermal stability up to a temperature of at least 700° C.

The adhesive is preferably selected from the group consisting of silicon, oxidic, nitridic or carbidic materials or mixtures hereof, in particular consists of SiOₓ with x=1-2, AlOₓ with x=1-2, SiCₓ with x=0.5-1.5, SiNₓ with x=0-2.5, ZnO:Al, TiN.

For particular preference, the adhesive has a temperature stability up to temperatures of 800 to 1,300° C., wherein there should be understood by temperature stability that, in this temperature range, essentially no metallic impurities are released. There should be understood by this that a surface-standardised flow of impurity atoms of less than 1×10¹¹ atoms per minute and cm² is released from the adhesive into the semiconductor layer by degassing and/or diffusion.

A further preferred embodiment provides that the adhesive comprises at least one filler. This is selected in particular from the group consisting of phyllosilicates, quartz particles, metal particles, silicon powder, ceramic powder and also mixtures hereof. The use of fillers is advantageous in particular when the surfaces of the semiconductor structure or of the substrate are not entirely planar so that the fillers enable equalisation of unevennesses in the surfaces of the substrate and/or of the semiconductor structure.

In a particularly preferred embodiment, the adhesive or the adhesive provided with filler has optical properties which enable reflection of at least 50% of the incident radiation in the wavelength range of 800 to 1,200 nm. As a result, the adhesive layer can serve as reflector layer within the semiconductor structure.

In the case of an electrically insulating substrate, the adhesive can be electrically insulating or electrically conductive. In the case of an electrically conducting substrate, the adhesive is preferably electrically conductive. In the case of an electrically semiconducting substrate, the adhesive is necessarily electrically conductive. The electrically conductive adhesive is thereby selected preferably from the group consisting of SiCₓ with x=0.5-1.5, ZnO:Al, TiN and silicon. The electrically insulating adhesive is preferably selected from the group consisting of SiOₓ with x=1-2, AlOₓ with x=1-2, SiCₓ with x=0.5-1.5, SiNₓ with x=0.1-2.5.

It is likewise possible that more than one semiconductor layer is applied on the substrate. A preferred variant provides for example that, on the first semiconductor layer—on the side orientated away from the substrate—an adhesive and, subsequently, at least one further semiconductor layer is applied, at least in regions. This process can be continued with any number of semiconductor layers.

In the case of a plurality of semiconductor layers, it is preferred that the semiconductor layers can have different physical properties. There are included in these physical properties, e.g. different spectral properties for absorption of incident radiation in different wavelength ranges or a different conductivity.

The at least one substrate and/or the at least one semiconductor layer have preferably, at least in regions, a porosity which enables any degassing produced during a thermal treatment to be removed. This porosity of substrate or semiconductor layer can be preferably in the range of 5 to 60%.

The material of the at least one substrate is preferably selected from the group consisting of silicon, sintered silicon, graphite, quartz, borosilicate glass, glass, ceramic materials and III-V compound semiconductors, in particular ZrSO₄, SiN, Al₂O₃, SiC, GaAs, InP, GaP, GaN, AlGaAsP, and also material composites hereof.

The semiconductor structure is preferably a solar cell, in particular a wafer equivalent solar cell, a multiple solar cell or a thin-film solar module.

According to the invention, a method for the production of a semiconductor structure, made of at least one substrate and at least one semiconductor layer, which has the previously described structure, is likewise provided. In the method, on the substrate and/or on the semiconductor layer, an adhesive and, subsequently, a semiconductor layer is applied, at least in regions, and, subsequently, the adhesive is cured thermally and/or chemically so that an integral bond between substrate and semiconductor layer is produced. A compound which has thermal stability up to a temperature of at least 700° C. is used as adhesive.

The application of a plurality of semiconductor layers is also possible by an adhesive being applied between each further semiconductor layer.

After the integral bond of substrate and at least one semiconductor layer, further process steps in the process chain for the production of semiconductor components can then be effected. There are included herein for example tempering, wet-chemical, dry-chemical or physical cleaning, epitaxial thickening, emitter diffusion, surface and/or bulk passivation, the application of an anti-reflective layer, front- or rear-side contacting, dry or wet etching processes or a combination hereof.

With respect to the method control, it is preferred that the application and curing of the adhesive is effected in a continuous process.

The previously described semiconductor structure is used preferably in solar cells or in a solar cell module.

The subject according to the invention is intended to be explained in more detail with reference to the subsequent Figure without wishing to restrict said subject to the specific embodiments shown here.

The Figure shows the spectrally resolved direct reflection of a silicon foil which is several 10 μm thick (“free-standing foil”) or after glueing with SiO₂ (“attached”).

It can be detected from the Figure that the entire light transmitted into the foil is absorbed in the wavelength range up to approx. 800 nm. The light reflected directly on the illuminated side (“front-side”) is measured. No difference between the individual treatment steps should be detected.

From approx. 870 nm, the curves attempt to separate before/after glueing. The curve without glueing shows the typical back-reflection of the light on the rear-side of a silicon foil which then emerges again at the front after passing through the foil from the rear-side towards the front-side and is detected there (called “escape peak” in technical jargon). Light which is transmitted without absorption and back-reflection emerges from the rear-side and is not measured.

In the case of the glued foil, the “escape peak” portion is greatly increased. The reason for this is the back-reflection of a part of the transmitted light by the adhesive layer into the foil and further towards the front-side where it emerges and is measured.

Between 800 nm and 870 nm, already transmitted light is also reflected back from the adhesive layer. The silicon layer thickness which is passed through once again is then however large enough to absorb the greater part of this light so that it does not contribute to increased reflection on the front-side.

1-16. (canceled)

17. A semiconductor structure made of at least one substrate and at least one semiconductor layer applied on the substrate, at least in regions, a first semiconductor layer being bonded integrally to the substrate, at least in regions, by means of a thermally and/or chemically cured adhesive and the cured adhesive having a thermal stability up to a temperature of at least 700° C., wherein the thermal stability means that essentially no metallic impurities are released at the indicated temperature.

18. The semiconductor structure according to claim 17, wherein the adhesive is selected from the group consisting of silicon, oxidic, nitridic and carbidic materials and mixtures thereof.

19. The semiconductor structure according to claim 17, wherein the adhesive has a thermal stability of up to 800 to 1,300° C.

20. The semiconductor structure according to claim 17, wherein the adhesive comprises at least one filler.

21. The semiconductor structure according to claim 17, wherein the adhesive reflects at least 50% of the incident radiation in the wavelength range of 800 to 1,200 nm.

22. The semiconductor structure according to claim 17, wherein, in the case of
a) an electrically insulating substrate, the adhesive is electrically insulating or electrically conductive;
b) an electrically semiconducting substrate, the adhesive is electrically conductive; and/or
c) an electrically conducting substrate, the adhesive is electrically conductive or electrically insulating.

23. The semiconductor structure according to claim 17, wherein, on the first semiconductor layer, an adhesive and, subsequently, at least one further semiconductor layer are present, at least in regions.

24. The semiconductor structure according to claim 23, wherein the semiconductor layers have different physical properties.

25. The semiconductor structure according to claim 17, wherein the at least one substrate and/or the at least one semiconductor layer has, at least in regions, an open porosity which is suitable for removing gases produced during a thermal treatment.

26. The semiconductor structure according to claim 17, wherein the material of the at least one substrate is selected from the group consisting of silicon, sintered silicon, graphite, quartz, borosilicate glass, glass, ceramic materials, and III-V compound semiconductors, and composites thereof.

27. The semiconductor structure according to claim 17, wherein the semiconductor structure is a solar cell.

28. A method for the production of a semiconductor structure made of at least one substrate and at least one semiconductor layer according to claim 17, in which
a) on the substrate, an adhesive and, subsequently, a first semiconductor layer is applied, at least in regions,
b) the adhesive is cured thermally and/or chemically and therewith an integral bond between substrate and semiconductor layer is produced, wherein the adhesive has thermal stability up to a temperature of at least 700° C.

29. The method according to claim 28, wherein, in addition, on the first semiconductor layer, an adhesive and, subsequently, at least one further semiconductor layer are applied, at least in regions, an integral bond being produced between the individual semiconductor layers by means of an adhesive.

30. The method according to claim 28, wherein further process steps follow after the integral bonding.

31. The method according to claim 28, wherein the application and curing of the adhesive are implemented in a continuous process.
